(19) United States
(12) Patent Application Publication
(10) Pub. No.: US 2020/0343691 A1
(43) Pub. Date: Oct. 29, 2020

(54) EPITAXIAL PLANARIZATION OF TUNNEL JUNCTION AND ALIKE VCSEL ARRAY AND METHOD THEREFOR

(71) Applicant: OEpic SEMICONDUCTORS, INC, SUNNYVALE, CA (US)

(72) Inventors: MAJID RIAZIAT, SUNNYVALE, CA (US); YI-CHING PAO, SUNNYVALE, CA (US); TA-CHUNG WU, SUNNYVALE, CA (US)

(21) Appl. No.: 16/924,783

(22) Filed: Jul. 9, 2020

Related U.S. Application Data
(62) Division of application No. 16/273,776, filed on Feb. 12, 2019.
(60) Provisional application No. 62/629,186, filed on Feb. 12, 2018.

(51) Int. Cl. H01S 5/183; H01S 5/30; H01S 5/42

(52) U.S. Cl. CPC H01S 5/18366; H01S 5/3095; H01S 5/026; H01S 5/423; H01S 5/18308

(57) ABSTRACT

A method of forming a Tunnel Junction (TJ) Vertical Cavity Surface Emitting Laser (VCSEL) array comprises forming a first mirror device on a substrate; forming an active region on the first mirror device; forming a first portion of a second mirror device on the active region; forming a plurality of tunnel junctions on the first portion of the second mirror device; and forming a second portion of the second mirror device through an epitaxial overgrowth, the second portion of the second mirror device covering the plurality of tunnel junctions, wherein individual VCSEL elements of the TJ VCSEL array are electrically connected through the epitaxial overgrowth of the second portion of the second mirror device.

### RELATED APPLICATIONS

This patent application is related to U.S. Provisional Application No. 62/629,186 filed Feb. 12, 2018, entitled “EPITAXIAL PLANARIZATION OF TUNNEL JUNCTION AND ALIKE VCSEL ARRAY” in the name of Majid Riaziat, Yi-Ching Pao and Ta-Chung Wu and which is incorporated herein by reference in its entirety. The present patent application claims the benefit under 35 U.S.C § 119(e).

### TECHNICAL FIELD

The present invention generally relates to vertical cavity surface emitting lasers (VCSELs) and, more particularly to, a tunnel junction (TJ) VCSEL array wherein elements of the TJ VCSEL array share a common regrown epitaxial top Distributed Braggs Reflector (DBR) layer.

### BACKGROUND

A junction formed at a boundary between a negatively doped (n-type) and a positively doped (p-type) semiconductor is known as a p-n junction. The p-n junction may form a diode that may allow current flow in one direction only, known as the forward direction. Reverse direction current is generally blocked. If the doping level in the two semiconductor regions is increased heavily (denoted as p++ and n++ doping) then a reverse current may “tunnel” through and the junction becomes a “tunnel junction”.

Tunnel junctions may be used in multi junction solar cells in order to be able to stack solar cell p-n junctions in the same polarity direction. The tunnel junction may allow the switching from p-type to n-type semiconductor without forming a rectifying junction.

In the case of an oxide VCSEL, each VCSEL has to be “etched” to form a cylindrical or pillar or mesa shape first in order to expose the oxide layer for subsequent oxidation process to take place as shown in FIGS. 1A and 1B. This process has to physically separate the individual VCSELs from others instead of sharing the same underlying substrate. This physical separation causes disconnect, both electrical and optical, of individual VCSELs in an array application when a large amount of VCSELs are placed close to each other. Electrically, this separation is remedied by additional processes of overlaying metals or metal traces to connect all VCSELs within an array. However, the optical disconnection between each VCSEL cannot be remedied easily after the individual pillar or mesa was formed by chemical or reactive plasma etch.

In a VCSEL, a tunnel junction (FIG. 1B) may be used to form two functions: (1) to convert the p-type mirror stack to an n-type mirror stack for reduced optical loss and improved electrical resistance; (2) to create an “electrically defined” aperture to confine lateral current flow and to limit the optical modes. Current confinement is currently done with either ion implantation isolation or an oxide aperture in conventional VCSELs.

Presently, there has only been limited prior art work done on individual tunnel junction structures but only for long wavelength (1.3 um-1.5 um) InP substrate based VCSELs. There have been no tunnel junction structures made on short wavelength (850 nm to up to 1100 nm) GaAs based VCSEL which require no VCSEL pillar or mesa etched to expose the oxide layer for subsequent aperture oxidation process. In this process, there would be no disconnect at the epitaxial level between individual VCSEL within the array.

Therefore, it would be desirable to provide a device and method that overcome the above problems. The device and method would provide a TJ VCSEL where there would be no disconnect at the epitaxial level between individual VCSEL within the array.

### SUMMARY

In accordance with one embodiment, a method of forming a Tunnel Junction (TJ) Vertical Cavity Surface Emitting Laser (VCSEL) package is disclosed. The method comprises: forming a first mirror device on a substrate; forming an active region on the first mirror device; forming a first portion of a second mirror above the active region; forming a plurality of tunnel junctions above the first portion of the second mirror; and forming a second portion of the second mirror device through an epitaxial overgrowth, the second portion of the second mirror device covering the plurality of tunnel junctions, wherein individual VCSEL elements of the TJ VCSEL array are electrically connected through the epitaxial overgrowth of the second mirror device.

In accordance with one embodiment, a method of forming a Tunnel Junction (TJ) Vertical Cavity Surface Emitting Laser (VCSEL) package is disclosed. The method comprises: forming a first Distributed Bragg Reflector (DBR) on a substrate; forming an active region on the first DBR; forming a first portion of a second DBR on the active region; forming a plurality of tunnel junctions on the first portion of the second DBR; and forming a second portion of the second DBR through an epitaxial overgrowth, the second portion of the second DBR covering the plurality of tunnel junctions, wherein individual VCSEL elements of the TJ VCSEL array are electrically connected through the epitaxial overgrowth of the second portion of the second DBR.

In accordance with one embodiment, a Tunnel Junction (TJ) Vertical Cavity Surface Emitting Laser (VCSEL) array is disclosed. The TJ VCSEL array has a substrate. A first Distributed Bragg Reflector (DBR) is formed on the substrate. An active region is formed on the first DBR, wherein the active region is a quantum well. A first portion of a second DBR is formed on the active region. A plurality of tunnel junctions is formed on the first portion of the second DBR. A second portion of the second DBR is formed through an epitaxial overgrowth, the second portion of the second DBR covering the plurality of tunnel junctions, wherein individual VCSEL elements of the TJ VCSEL array are electrically connected through the epitaxial overgrowth of the second portion of the second DBR, wherein the epitaxial overgrowth is used for planarization of the TJ VCSEL array.

### BRIEF DESCRIPTION OF THE DRAWINGS

The present application is further detailed with respect to the following drawings. These figures are not intended to limit the scope of the present application but rather illustrate certain attributes thereof. The same reference numbers will be used throughout the drawings to refer to the same or like parts.

FIGS. 1A-1B are cross-sectional views showing differences between a typical TJ VCSEL and an oxide aperture VCSEL;

FIG. 2 shows a cross-sectional view of a prior art VCSEL array;

FIG. 3 is cross-sectional view showing an exemplary embodiment of TJ VCSEL array formed in accordance with one aspect of the present application; and

FIG. 4 is cross-sectional view showing an exemplary embodiment of a flip chip TJ VCSEL array formed in accordance with one aspect of the present application.

### DESCRIPTION OF THE APPLICATION

The description set forth below in connection with the appended drawings is intended as a description of presently preferred embodiments of the disclosure and is not intended to represent the only forms in which the present disclosure can be constructed and/or utilized. The description sets forth the functions and the sequence of steps for constructing and operating the disclosure in connection with the illustrated embodiments. It is to be understood, however, that the same or equivalent functions and sequences can be accomplished by different embodiments that are also intended to be encompassed within the spirit and scope of this disclosure.

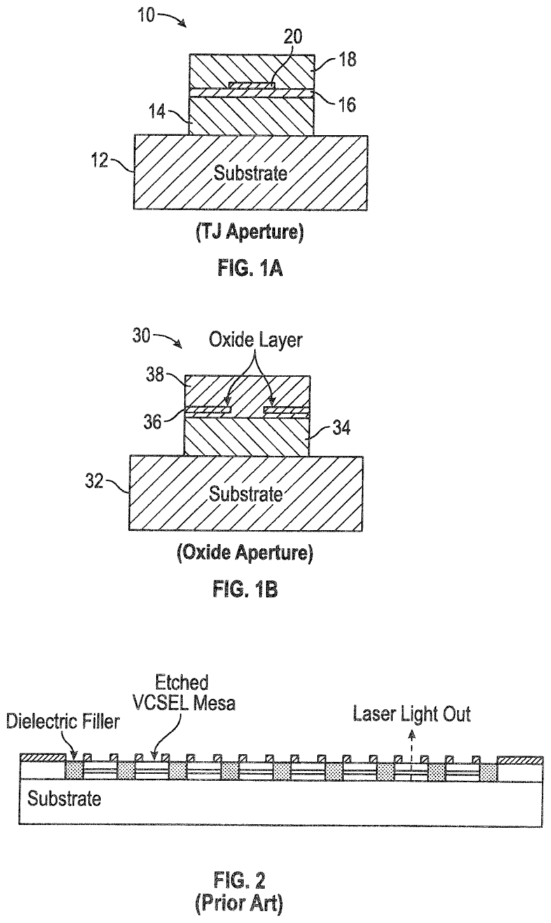

Referring to FIGS. 1A and 1B, cross-sectional views showing differences between a typical TJ VCSEL 10 and an oxide aperture VCSEL 30 may be seen. In general, in a TJ VCSEL 10 a TJ is “buried” under a top DBR layer growth while the oxide aperture VCSEL 30 requires no regrowth rather an oxide aperture is formed after the complete epi structure is grown and VCSEL pillar or mesa is etched to expose the oxide layer on the side wall. Basically, the TJ VCSEL 10 can have arbitrary aperture shape as it is completely defined by photolithography and not by side wall oxidation which alters and rounds up the shape of the mesa-based oxide aperture.

The TJ VCSEL 10 may be formed on a substrate 12. The substrate 12 may be formed of Gallium Arsenide (GaAs), Indium phosphide (InP) or similar material. A distributed Bragg reflector (DBR) N-mirror 14 may be situated on the substrate 12. The DBR N-mirror 14 may be composed of a plurality of pairs of layers. Each pair of layers may be InGaAsP and InP, AlGaAsSb and InP, or AlGaPSb and InP. The above layers are given as examples and should not be seen in a limiting manner. Each layer of the pair is about one-fourth of the optical design wavelength (λ) of light to be emitted by the TJ VCSEL 10.

An active region 16 may be formed on the DBR N-mirror 14. The active region 16 may be formed of one or more quantum wells for laser light generation. A DBR P-mirror 18 may be formed on the active region 16. The DBR P-mirror 18 be composed of a plurality of pairs of layers. Each layer of the pair is about one-fourth of the optical design wavelength (λ) of light to be emitted by the TJ VCSEL 10 and P-doped.

A tunnel junction 20 may be formed within the DBR P-mirror 18. The tunnel junction 20 may be formed of a highly doped P material adjacent to a highly doped N material that results in the junction. For example, the materials may include InAlGaAs and InP. The above materials are given as examples and should not be seen in a limiting manner.

Referring to FIG. 1B, the oxide aperture VCSEL array 30 may be formed on a substrate 32. The substrate 32 may be a gallium arsenide (GaAs) substrate 32 or similar material. A pair of Distributed Braggs Reflectors (DBR) 34 and 38 may be formed on the substrate 32 and runs parallel to the substrate 32. The DBRs 34 and 38 may be formed of a plurality of layers. The DBRs 34 and 38 may be formed by disposing multiple layers of alternating materials with varying optical impedances. In general, the multiple layers alternate between high and low optical impedances. An active region 36 may be formed between the pair of DBRs 34 and 38. The active region 36 may be formed of one or more quantum wells for laser light generation.

Most high performance and high-speed GaAs based VCSELs have a current-limiting aperture formed by the oxidation of a semiconductor layer that gets converted to aluminum oxide in a controlled lateral wet oxidation process. Other GaAs based VCSELs use vertical ion implantation to form the aperture. Longer wavelength VCSELs in the wavelength range of 1.3-1.5 um are built on InP substrates which use tunnel junctions to form the aperture because there is no readily available oxide layer in InP based material system. Presently there has been no successful tunnel junction VCSEL products have been reported in shorter wavelength GaAs based VCSELs.

The present invention provides a Tunnel Junction (TJ) VCSEL where there would be no disconnect at the epitaxial level between individual VCSEL within a VCSEL array. A TJ VCSEL promises significant performance advantages over oxide-aperture VCSELs, by using a laterally structured TJ within the p-side of the laser. Some of the advantages are, but not limited to: (1) higher emission uniformity can be attained over large-area VCSEL arrays since the apertures are very well defined by lithography; (2) small-aperture VCSEL devices can be fabricated more reproducibly and uniformly; (3) VCSEL devices may have higher reliability since there is no strained oxide layer within the semiconductor matrix; (4) the majority of the p-side distributed DBR layers are converted to n-doped materials resulting in lower electrical resistance of the DBR and lower free carrier absorption.

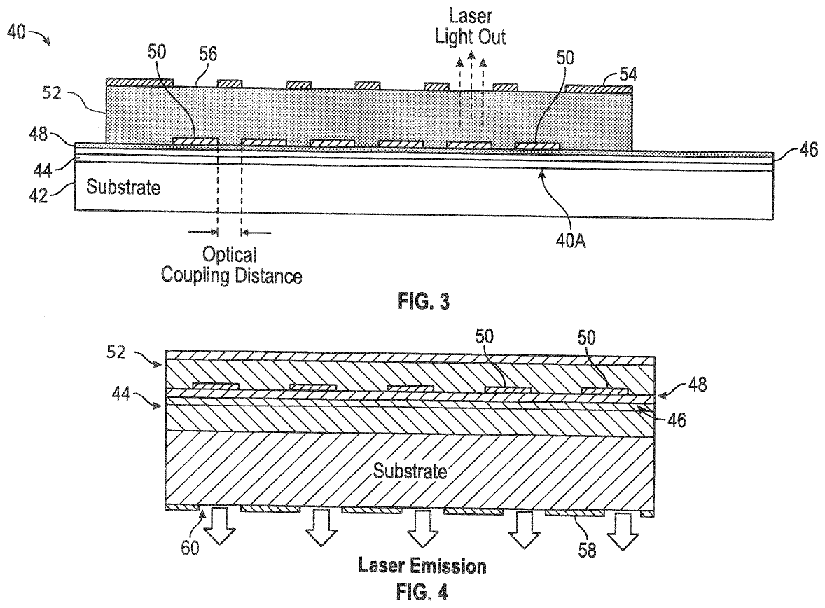

Referring to FIG. 3, a method for forming a TJ VCSEL array 40 may be disclosed. The BJT VCSEL 40 may have a substrate 42. The substrate 42 may be formed of Gallium Arsenide (GaAs), Indium phosphide (InP) or similar material. A distributed Bragg reflector (DBR) N-mirror 44 may be formed on the substrate 42 through metal deposition. The DBR N-mirror 44 may be composed of a plurality of pairs of layers which are deposited on top of one another forming the DBR N-mirror 44. Each pair of layers may be InGaAsP and InP, AlGaAsSb and InP, or AIGaPSb and InP. The above layers are given as examples and should not be seen in a limiting manner. Each layer of the pair is about one-fourth of the optical design wavelength (λ) of light to be emitted by the TJ VCSEL 40. The metal layers may be deposited in different manners. In accordance with one embodiment, Chemical Vapor Deposition (CVD) may be used.

An active region 46 may be formed on the DBR N-mirror 44. The active region 46 may be formed of one or more quantum wells for laser light generation. The active region may be faulted by through CVD or similar processes.

A first portion of a DBR P-mirror 48 may be formed through metal deposition on the active region 46. The first portion of the DBR P-mirror 48 may be composed of a plurality of pairs of layers. Each layer of the pair is about one-fourth of the optical design wavelength (λ) of light to be emitted by the TJ VCSEL 40 and P-doped. The metal layers may be deposited in different manners. In accordance with one embodiment CVD may be used to form the DBR P-mirror 48.

A plurality of tunnel junctions 50 may be formed within the first portion of the DBR P-mirror 48 and above the active region 46 through a metal deposition process. Each tunnel junction 50 may be formed of a highly doped P material adjacent to a highly doped N material that results in the junction. For example, the materials may include InAlGaAs and InP. The above is given as examples and should not be seen in a limiting manner.

A second portion of the DBR P-mirror 52 may be formed by metal deposition over and covering the plurality of tunnel junctions 50. In the present embodiment an epitaxy deposition process may be used to form the second portion of the DBR-mirror 52. In an epitaxy deposition process, an epitaxial film or epitaxial layer may be applied to cover the plurality of tunnel junctions 50.

In the embodiment shown in FIG. 3, metal contacts 54 may be formed on a top surface of the second portion of the DBR PN-mirror 52. The metal contacts 54 may be formed through different types of metal deposition processes. Apertures 56 may be formed between the metal contacts 54. The apertures may allow light generated by TJ VCSEL elements 40A of the TJ VCSEL array 40 to be distributed outward.

Since each TJ VCSEL element 40A of the TJ VCSEL array 40 share the same regrown epitaxial layer of the second portion of the DBR P-mirror 52, the distance to each other can be determined by design (optical coupling distance). The BJT VCSEL array 40 can be very dense with short distances among the individual TJ VCSEL elements 40A if optical interaction is desired. Optical interaction can phase lock adjacent individual TJ VCSEL elements 40A to form an array with coherent emission. It is also possible with tunnel junctions to merge apertures 56 or to form apertures 56 with an arbitrary geometrical shape in order to engineer the shape of the output beam. This invention can also apply to any TJ-like VCSEL which use other means to control and direct the current flow as long as the aperture is “defined and buried” within the overgrown epitaxy layer without any pillar or mesa etch based oxidation process to define and fabricate the VCSEL aperture.

Since the individual TJ VCSEL elements 40A share the same regrowth epitaxial layer of the second portion of the DBR P-mirror 52, and at the same time the buried TJs 50, after it is lithographically defined and formed, it requires no exposure of the side wall to subsequent oxidation process to take place, thus offering a unique way to construct the VCSEL array in a more straightforward and advantageous way, both optically and electrically.

The current invention calls for using the unique feature of no individual pillar or mesa etch of the TJ VCSEL elements 40A and share the top overgrown DBR P-mirror 52 epitaxial layer for both electrical and optical connection and coupling. In contrast, as shown in FIG. 2, a prior art VCSEL array may be seen for direct comparison which shows that all individual VCSEL elements are physically separated by pillar or mesa etch, and trench filled with spin-on dielectric to form some kind of surface planarization. Since the dielectric material are nonconductive electrically, additional overhead of lithography and metal connections must be applied to connect to each VCSEL. This also forces the spacing between individual VCSEL elements to stay above certain distance to accommodate the overhead of metal connection requirement.

On the contrary the TJ VCSEL array 40 offers the advantages of no pillar or mesa etch being required. Thus, all individual VCSEL elements 40A within the TJ VCSEL array 40 remain “epitaxial” connected and default planarization is achieved by the shared DBR P-mirror 52 regrowth epitaxial layer. This may allow each individual VCSEL element 40A to be placed very close to one another, giving the benefits of shared electrical top contact for low series resistance and much dense array arrangements with a given number of individual VCSEL elements 40A to be placed within the TJ VCSEL array 40.

Furthermore, when individual VCSEL elements 40A can be placed very close to each other, within a distance of less than or comparable to the laser wave length of several microns, optical coupling among these closely spaced individual VCSEL elements 40A become feasible. This will lead to a coherent laser light output collectively from an array of individual VCSEL elements 40A, and even make the steering of the laser light possible. Also, the thickness of DBR P-mirror 52 can be minimized to even zero hence increasing the possibility of out-of-phase optical coupling (if the DBR P-mirror 52 doping on top is high enough), which may be the opposite of in-phase coupling but useful in different applications.

The current invention of epitaxial planarization of TJ VCSEL array 40 may also be suited for flip chip configuration when the TJ VCSEL elements 40A are used for backside illumination as shown in FIG. 3. When TJ VCSEL array 40 is used for backside illumination, certain planarization process may be required to level and protect a front surface 40B. In this embodiment, metal contacts 58 may be formed on a bottom surface of the substrate 42. The metal contacts 58 may be formed through different types of metal deposition processes. Apertures 60 may be formed between the metal contacts 58. The apertures may allow light generated by TJ

VCSEL elements 40A of the TJ VCSEL array 40 to be distributed outward. This current invention of epitaxial planarization of the TJ VCSEL array 40 may offer the needed planarization with the overgrown top DBR layer by design and by default for any flip chip-based backside illuminating VCSEL.

While embodiments of the disclosure have been described in terms of various specific embodiments, those skilled in the art will recognize that the embodiments of the disclosure may be practiced with modifications within the spirit and scope of the claims.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. A Tunnel Junction (TJ) Vertical Cavity Surface Emitting Laser (VCSEL) array comprising:
a substrate;
a first Distributed Bragg Reflector (DBR) formed on the substrate;
an active region formed on the first DBR, wherein the active region is a quantum well;
a first portion of a second DBR formed on the active region;
a plurality of tunnel junctions formed on the first portion of the second DBR; and
a second portion of the second DBR formed through an epitaxial overgrowth, the second portion of the second DBR covering the plurality of tunnel junctions, wherein individual VCSEL elements of the TJ VCSEL array are electrically connected through the epitaxial overgrowth of the second portion of the second DBR, wherein the epitaxial overgrowth is used for planarization of the TJ VCSEL array.

13. The TJ VCSEL array of claim 12, comprising a plurality of contacts formed on a top surface of the second portion of the second DBR, wherein an opening is formed between adjacent contacts of the plurality of contacts, each individual opening aligned with a corresponding tunnel junction of the plurality of tunnel junctions.

14. The TJ VCSEL array of claim 12, comprising a plurality of contacts formed on the substrate for flip chip mounting of the TJ VCSEL array, wherein an individual opening is formed between adjacent contacts of the plurality of contacts, each individual opening aligned with a corresponding tunnel junction of the plurality of tunnel junctions.

15. The TJ VCSEL array of claim 12, wherein spacing between adjacent tunnel junctions is a design parameter for applicable optical coupling.

16. The TJ VCSEL array of claim 12, wherein a distance between adjacent tunnel junctions is less than a predefined distance to optically coupled adjacent VCSEL elements of the TJ VCSEL array.
